(19) United States
(12) Patent Application Publication
(10) Pub. No.: US 2014/0299356 A1
(43) Pub. Date: Oct. 9, 2014

(54) PROTECTIVE FILM WITH DYE MATERIALS FOR LASER ABSORPTION ENHANCEMENT FOR VIA DRILLING

(71) Applicants: Chong Zhang, Chandler, AZ (US); Nikhil Sharma, Chandler, AZ (US)

(72) Inventors: Chong Zhang, Chandler, AZ (US); Nikhil Sharma, Chandler, AZ (US)

(21) Appl. No.: 13/856,806

(22) Filed: Apr. 4, 2013

(51) Int. Cl. H05K 3/40; H05K 1/11; H05K 3/00

(52) U.S. Cl. CPC H05K 3/4038; H05K 3/0076; H05K 1/11
USPC 174/250; 29/885; 29/852

(57) ABSTRACT

Embodiments of preventing unwanted damage to microelectronic substrates from laser drilling are generally described herein. In some embodiments, the method includes forming a microelectronic substrate, and adding a layer of protective material to dielectric material of the microelectronic substrate. The microelectronic substrate is configured for mounting one or more integrated circuits (ICs) thereon and includes interconnection for a plurality of electronic circuits. The protective material is configured to absorb laser energy applied in laser drilling of the microelectronic substrate.

### TECHNICAL FIELD

Embodiments pertain to manufacturing of electronic systems that include integrated circuits (ICs). Some embodiments relate to laser drilling of microelectronic substrates.

### BACKGROUND

Manufacturing of electronic systems can include a stage where vias are added to an electronic substrate. A via in a substrate provides electrical continuity between layers in the substrate, and the via traverses one or more intervening layers between the layers being electrically connected. As the size of features in electronic systems continues to decrease, the size of vias also is decreasing. Vias can be formed in an electronic substrate by laser drilling a via hole between layers to be electrically connected and then filling the laser-drilled opening with metal. One issue with laser drilling is that it can be difficult to limit the laser energy to the desired region for the via. This can result in damage to the substrate beyond the via region. Thus there are general needs for methods and systems to improve the via formation process.

### BRIEF DESCRIPTION OF THE DRAWINGS

FIG. 1 is a flow diagram of an example of a method to reduce or eliminate damage when laser drilling in accordance with some embodiments; and

FIGS. 2A-2D illustrate a microelectronic substrate under process in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

As explained previously herein, the size of vias is decreasing as the size of features in substrates continues to decrease. Consequently, laser drilling of a via can cause damage beyond the region desired for the via. For vias with a diameter less than approximately fifty micrometers (50 μm), ring shaped damage to the substrate has been observed at the periphery region of a via. This damage may be due to a diffracted side lobe of the laser beam or an optical aberration.

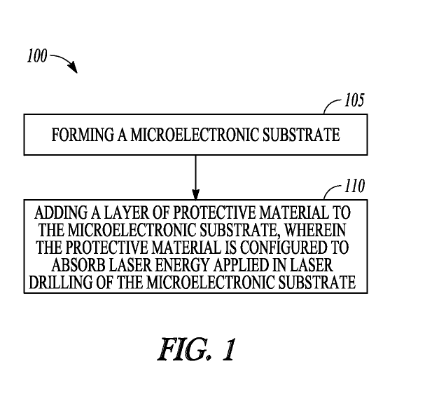

FIG. 1 is a flow diagram of an example of a method 100 to reduce or eliminate damage when laser drilling vias. At block 105, a microelectronic substrate is formed. The microelectronic substrate can be configured for mounting or packaging one or more integrated circuits (ICs). The microelectronic substrate includes interconnection for a plurality of electronic circuits.

At block 110, a layer of protective material is added to raw dielectric material which will be laminated to the micro-electronic substrate to form an insulating layer. The protective material is configured to absorb laser energy applied in laser drilling of the microelectronic substrate. The protective layer can include an additive material to absorb laser energy and prevent damage to the dielectric material beyond the via area. The layer of protective material can be a removable layer. In some examples, the method 100 includes laser drilling one or more via holes in the microelectronic substrate and removing the layer of protective material from the microelectronic substrate after the laser drilling. The via holes may be drilled using a carbon dioxide (CO₂) laser, an ultraviolet (UV) laser (355 nanometer) or other types of lasers. In some examples, the via holes have a diameter of 120 micrometers (120 μm) or less. A metal layer can be added to the microelectronic substrate to fill in the laser-drilled opening and form the via.

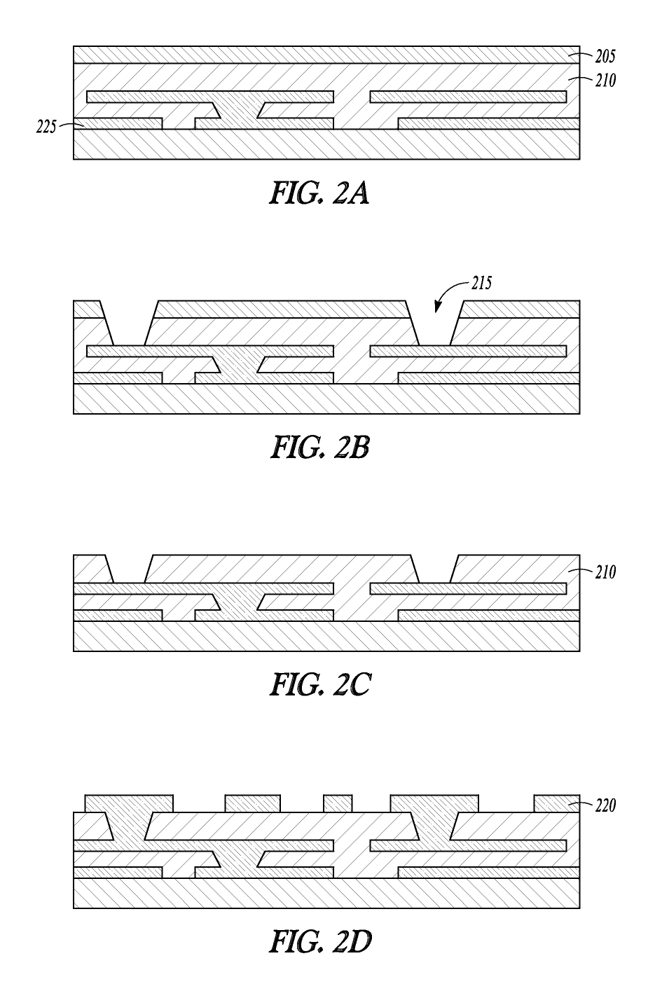

FIGS. 2A through 2D illustrate an example of the method 100 to reduce or eliminate damage when laser drilling vias. The Figures illustrate a cross-section of a microelectronic substrate under process. The microelectronic substrate may be a substrate included in a package for one or more ICs, such as a thick core substrate, a thin core substrate, laminated core substrate or coreless substrate.

In some examples, the microelectronics substrate is included in a flip-chip integrated circuit package. In flip chip packaging, interconnection pads for an IC are arranged on the IC and solder bumps can be added as the interconnection. The IC is mounted to the microelectronic substrate through solder bumps.

The microelectronic substrate in FIGS. 2A-2D includes a conductive layer 225 for electronic circuits. Vias can be formed in the microelectronic substrate to provide electrical continuity to portions of the circuits. The microelectronic substrate may then be used to package one or more ICs such as a processor IC, digital signal processor IC, memory IC, or radio frequency IC (RFIC).

In FIG. 2A, a protective layer 205 is added to the microelectronic substrate. In some examples, the protective layer is added above a dielectric layer 210 of the microelectronic substrate. In certain examples, the protective layer 205 includes a layer of protective film that is laminated onto the surface of the microelectronic substrate. In other examples, the protective layer 205 is added to the microelectronic substrate by vacuum lamination, spin/roll coating, or screen printing.

In some examples, the protective layer is not added as an additional process step of manufacturing. The protective layer can be included in a carrier film for the dielectric raw material used in making the microelectronic substrate. Prior to the manufacturing process, the raw material can be delivered on the carrier film that has the laser absorbing properties. During the manufacturing process, the uncured raw material polymer film can be applied to a semi-finished substrate. The dielectric may then be cured and laser drilling can be conducted. After the laser drilling of the dielectric material, the carrier film (that contains the laser absorber) can be peeled off and removed.

In FIG. 2B, one or more via openings 215 are formed in the microelectronic substrate by laser drilling of the protective layer and the dielectric layer. The protective layer absorbs laser energy applied in the laser drilling of the vias to prevent or reduce damage to the underlying layers that extends beyond the desired via area. To absorb the laser energy, the protective layer may include a dye that absorbs laser energy of a wavelength range used in laser drilling of a via in the micro-electronic substrate. Some examples of ranges of wavelengths of laser energy used in the laser drilling include 9.3 μm to 10.7 μm, 193 nanometers (nm) to 355 nm, 520 nm to 560 nanometers, and 1020 nm to 1080 nm. The dye can be selected to match the wavelength used in the laser drilling.

In FIG. 2C, the protective layer 205 is removed from the microelectronic substrate. In some examples, the protective layer 205 is a removable layer that can be peeled away from the substrate either manually or by a device. In some examples, the protective layer 205 is sacrificial layer that is removed from the substrate by dissolving the protective layer 205. In FIG. 2D, a layer of metal 220 is added (e.g., by electro-less and electrolytic copper plating) to the microelectronic substrate to form the vias and electric circuits after the protective layer is removed.

According to some examples, the protective layer 205 is a layer of polyethelene terephthalate (PET) film. The layer of PET film can include the dye that absorbs the desired laser energy. The dye can be physically blended into the PET film, chemically incorporated into the PET polymer architecture of the film, or added by any other physico-chemical method. The PET layer can be added during the manufacturing process or the layer can be a carrier film for the dielectric raw material for the dielectric layer 210. The carrier film may be peeled off subsequent to lamination and drilling of the substrate layers.

In some examples, the protective layer 205 can include a chromophore material that absorbs the laser energy. A chromophore absorbs electromagnetic energy of certain wavelength incident to the chromophore, depending on the properties of the chromophore material. In certain examples, the chromophore contains at least one of a carbon-oxygen functional group, a carbon-sulfur functional group, or a silicon-oxygen-R functional group, wherein R is an alkyl group. In certain examples, the protective layer contains a chromophore material that includes at least one of polyphenyl 2, cyanine, pyrylium, thiapyrilium, squarylium, croindoaniline, an azo compound, a metalated azo compound, anthrquinone, napthpquinone, aminium radical salt, phthalocynine, naphthalocynine, bis(dithiolene) and thiobenzophenone.

Presently, for laser drilling of vias less than 60 μm, the drilling rate needs to be reduced to reduce unwanted laser damage to the substrates. By adding dye material in a protective film for laser energy absorption, unwanted surface damage to microelectronic substrates can be avoided without managing the laser energy and drilling rate during the process. This allows laser drilling of via openings having a diameter less than or equal to 60 μm with higher laser energy and faster drilling speed. This can improve throughput of manufacturing microelectronic substrates.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

### ADDITIONAL EXAMPLES

Example 1 can include subject matter (such as an apparatus) including a microelectronic substrate under process, wherein the microelectronic substrate is configured for mounting one or more integrated circuits (ICs) thereon and includes a dielectric material and interconnection for a plurality of electronic circuits; and a layer of protective material on top of the dielectric material, wherein the layer of protective material is configured to absorb laser energy applied in laser drilling of the dielectric material of the microelectronic substrate.

In Example 2, the subject matter of Example 1 can optionally include a protective layer that is a removable layer that contains a dye. The dye is configured to absorb laser energy of a wavelength range used in laser drilling of a via in the dielectric material.

In Example 3, the subject matter of one or a combination of Examples 1 and 2 can optionally include a protective layer that is removable and includes chromophore material. The chromophore material is configured to absorb laser energy applied when laser drilling the dielectric material.

In Example 4, the subject matter of one or any combination of Examples 1-3 optionally includes a protective layer that includes chromophore material. The chromophore material can include at least one of a carbon-oxygen functional group, a carbon-sulfur functional group, or a silicon-oxygen-R functional group, wherein R is an alkyl group.

In Example 5, the subject matter of one or any combination of Examples 1-4 optionally includes a protective layer that includes at least one of polyphenyl 2, cyanine, pyrylium, thiapyrilium, squarylium, croindoaniline, an azo compound, a metalated azo compound, anthrquinone, napthpquinone, aminium radical salt, phthalocynine, naphthalocynine, bis(dithiolene) and thiobenzophenone.

In Example 6, the subject matter of one or any combination of Examples 1, 4 and 5 optionally includes a protective layer that is a sacrificial layer that includes an additive configured to absorb laser energy used in laser drilling of a via in the dielectric material.

In Example 7, the subject matter of one or any combination of Examples 1-5 optionally includes a protective layer that includes a layer of removable PET film on top of a layer of dielectric material. The layer of PET film can include at least one of dye and/or a chromophore material configured to absorb the laser energy used in laser drilling of a via opening in the microelectronic substrate.

In Example 8, the subject matter of one or any combination of Examples 1-7 optionally include a microelectronic substrate that is included in an integrated circuit package.

Example 9 can include subject matter, or can optionally be combined with one or a combination of Examples 1-8 to include subject matter (such as a method, means for performing acts, or a machine readable medium that can cause the machine to perform acts) including forming a microelectronic substrate and adding a protective layer to the microelectronic substrate. The microelectronic substrate may be configured for mounting one or ICs thereon and includes dielectric material and interconnection for a plurality of electronic circuits. The protective layer can be added onto the dielectric material of the microelectronic substrate, and the protective material can be configured to absorb laser energy applied in laser drilling of the dielectric material.

In Example 10, the subject matter of Example 9 optionally includes adding a removable layer of protective material that contains an additive configured to absorb laser energy of a wavelength range used in laser drilling of a via in the dielectric material.

In Example 11, the subject matter of one or any combination of Examples 9 and 10 optionally include adding a protective layer that contains an additive configured to absorb laser energy, used in laser drilling, having a wavelength range of one of 9.3 micrometers to 10.7 micrometers, 193 nanometers to 355 nanometers, 520 nanometers to 560 nanometers, 1020 nanometers to 1080 nanometers.

In Example 12, the subject matter of one or any combination of Examples 9-11 optionally includes adding a removable layer of protective material that includes a chromophore material configured to absorb laser energy of a wavelength range used in laser drilling of the microelectronic substrate.

In Example 13, the subject matter of one or any combination of Examples 9-12 optionally includes adding a protective layer that contains a chromophore configured to absorb laser energy having a wavelength range of one of 9.3 micrometers to 10.7 micrometers, 193 nanometers to 355 nanometers, 520 nanometers to 560 nanometers, 1020 nanometers to 1080 nanometers.

In Example 14, the subject matter of one or any combination of Examples 9-13 optionally includes adding a protective layer that includes a chromophore containing at least one of a carbon-oxygen functional group, a carbon-sulfur functional group, or a silicon-oxygen-R functional group, wherein R is an alkyl group.

In Example 15, the subject matter of one or any combination of Examples 9-14 optionally includes adding a protective layer that includes at least one of polyphenyl 2, cyanine, pyrylium, thiapyrilium, squarylium, croindoaniline, an azo compound, a metalated azo compound, anthrquinone, napthpquinone, aminium radical salt, phthalocynine, naphthalocynine, bis(dithiolene) and thiobenzophenone.

In Example 16 the subject matter of one or any combination of Examples 9-15 optionally includes laser drilling one or more via holes in the microelectronic substrate, removing the layer of protective material from the microelectronic substrate, and adding a metal layer to the microelectronic substrate.

In Example 17, the subject matter of one or any combination of Examples 9-16 optionally includes laser drilling one or more via holes having a diameter of 120 micrometers (120 μm) or less in the microelectronic substrate.

In Example 18, the subject matter of one or any combination of Examples 9-15 optionally includes adding a removable protective layer on top of a layer of the dielectric material, wherein the removable protective layer includes a dye material, wherein the method further includes laser drilling, through the protective layer, one or more via openings in the layer of dielectric material, and wherein the dye material is configured to absorb laser energy of a wavelength range used in the laser drilling.

Example 19 can include subject matter, or can optionally be combined with one or a combination of Examples 1-18 to include subject matter (such as an apparatus) including a microelectronic substrate, wherein the microelectronic substrate is configured for mounting one or more integrated circuits (ICs) thereon and includes a dielectric material and interconnection for a plurality of electronic circuits, and means for absorbing laser energy applied in laser drilling of the microelectronic substrate.

In Example 20, the subject matter of Example 19 optionally includes means for absorbing laser energy having a wavelength range of one of 9.3 micrometers to 10.7 micrometers, 193 nanometers to 355 nanometers, 520 nanometers to 560 nanometers, 1020 nanometers to 1080 nanometers.

In Example 21, the subject matter of one or any combination of Examples 19 and 20 optionally includes a means for absorbing laser energy that includes a layer of the microelectronic substrate that is removable.

Example 22 can include, or can optionally be combined with any portion or combination of any portions of any one or more of Examples 1 through 21 to include, subject matter that can include means for performing any one or more of the functions of Examples 1 through 21, or a machine-readable medium including instructions that, when performed by a machine, cause the machine to perform any one or more of the functions of Examples 1 through 21.

Each of these non-limiting examples can stand on its own, or can be combined in various permutations or combinations with one or more of the other examples.

What is claimed is:

1. An apparatus comprising:
a microelectronic substrate under process, wherein the microelectronic substrate is configured for mounting one or more integrated circuits (ICs) thereon and includes a dielectric material and interconnection for a plurality of electronic circuits; and a layer of protective material on top of the dielectric material, wherein the layer of protective material is configured to absorb laser energy applied in laser drilling of the dielectric material of the microelectronic substrate.

2. The apparatus of claim 1, wherein the protective layer is a removable layer that contains a dye configured to absorb laser energy of a wavelength range used in laser drilling of a via in the dielectric material.

3. The apparatus of claim 1, wherein the protective layer is a removable layer that includes a chromophore material configured to absorb laser energy applied when laser drilling the dielectric material.

4. The apparatus of claim 3, wherein the protective layer includes a chromophore material containing at least one of a carbon-oxygen functional group, a carbon-sulfur functional group, or a silicon-oxygen-R functional group, wherein R is an alkyl group.

5. The apparatus of claim 1, wherein the protective layer is a sacrificial layer that includes at least one of polyphenyl 2, cyanine, pyrylium, thiapyrilium, squarylium, croindoaniline, an azo compound, a metalated azo compound, anthrquinone, napthpquinone, aminium radical salt, phthalocynine, naphthalocynine, bis(dithiolene) and thiobenzophenone.

6. The apparatus of claim 1, wherein the protective layer is a sacrificial layer that includes an additive configured to absorb laser energy used in laser drilling of a via in the dielectric material.

7. The apparatus of claim 1, wherein the protective layer includes a layer of removable polyethylene terephthalate (PET) film on top of a layer of dielectric material, and wherein the layer of PET film includes at least one of dye or a chromophore configured to absorb the laser energy used in laser drilling of a via opening in the microelectronic substrate.

8. The apparatus of claim 1, wherein the microelectronic substrate is included in an integrated circuit package.

9. A method comprising:
forming a microelectronic substrate, wherein the microelectronic substrate is configured for mounting one or more integrated circuits (ICs) thereon and includes dielectric material and interconnection for a plurality of electronic circuits; and
adding a layer of protective material onto the dielectric material of the microelectronic substrate, wherein the protective material is configured to absorb laser energy applied in laser drilling of the dielectric material.

10. The method of claim 9, wherein adding the layer of protective material includes adding a removable layer of protective material that contains an additive configured to absorb laser energy of a wavelength range used in laser drilling of a via in the dielectric material.

11. The method of claim 10, wherein adding a removable layer of protective material includes adding a protective layer that contains an additive configured to absorb laser energy, used in laser drilling, having a wavelength range of one of 9.3 micrometers to 10.7 micrometers, 193 nanometers to 355 nanometers, 520 nanometers to 560 nanometers, 1020 nanometers to 1080 nanometers.

12. The method of claim 9, wherein adding the layer of protective material includes adding a removable layer of protective material that includes a chromophore material configured to absorb laser energy of a wavelength range used in laser drilling of the microelectronic substrate.

13. The method of claim 12, wherein adding a removable layer of protective material that includes a chromophore material includes adding a protective layer that contains a chromophore configured to absorb laser energy having a wavelength range of one of 9.3 micrometers to 10.7 micrometers, 193 nanometers to 355 nanometers, 520 nanometers to 560 nanometers, 1020 nanometers to 1080 nanometers.

14. The method of claim 12, wherein adding a protective layer that includes a chromophore material includes adding a protective layer that includes a chromophore containing at least one of a carbon-oxygen functional group, a carbon-sulfur functional group, or a silicon-oxygen-R functional group, wherein R is an alkyl group.

15. The method of claim 9, wherein adding a protective layer includes adding a protective layer that contains at least one of polyphenyl 2, cyanine, pyrylium, thiapyrilium, squarylium, croindoaniline, an azo compound, a metalated azo compound, anthrquinone, napthpquinone, aminium radical salt, phthalocynine, naphthalocynine, bis(dithiolene) and thiobenzophenone.

16. The method of claim 9, including:
laser drilling one or more via holes in the microelectronic substrate;
removing the layer of protective material from the microelectronic substrate; and
adding a metal layer to the microelectronic substrate.

17. The method of claim 16, wherein laser drilling one or more via holes in the microelectronic substrate includes laser drilling one or more via holes having a diameter of 120 micrometers (120 μm) or less in the microelectronic substrate.

18. The method of claim 9, wherein adding layer of protective material to the microelectronic substrate includes adding a removable protective layer on top of a layer of the dielectric material, wherein the removable protective layer includes a dye material, wherein the method further includes laser drilling, through the protective layer, one or more via openings in the layer of dielectric material, and wherein the dye material is configured to absorb laser energy of a wavelength range used in the laser drilling.

19. An apparatus comprising:
a microelectronic substrate, wherein the microelectronic substrate is configured for mounting one or more integrated circuits (ICs) thereon and includes interconnection for a plurality of electronic circuits; and
means for absorbing laser energy applied in laser drilling of the microelectronic substrate.

20. The apparatus of claim 19, wherein the means for absorbing laser energy includes means for absorbing laser energy having a wavelength range of one of 9.3 micrometers to 10.7 micrometers, 193 nanometers to 355 nanometers, 520 nanometers to 560 nanometers, 1020 nanometers to 1080 nanometers.

21. The apparatus of claim 19, wherein the means for absorbing laser energy includes a layer of the microelectronic substrate that is removable.
